(19) United States
(12) Patent Application Publication
(10) Pub. No.: US 2024/0337771 A1
(43) Pub. Date: Oct. 10, 2024

(54) DENSITY INVERSION METHOD, APPARATUS AND ELECTRONIC DEVICE

(71) Applicant: THE INSTITUTE OF GEOLOGY AND GEOPHYSICS, CHINESE ACADEMY OF SCIENCES, Beijing (CN)

(72) Inventors: Zhenli WANG, Beijing (CN); Shuyang ZHANG, Beijing (CN)

(21) Appl. No.: 18/575,679

(22) PCT Filed: Jul. 4, 2022
(86) PCT No.: PCT/CN2022/103728

§ 371 Date: Dec. 29, 2023

(30) Foreign Application Priority Data
Jul. 5, 2021 (CN) 202110768231.7

(51) Int. Cl. G01V 7/06

(52) U.S. Cl. CPC G01V 7/06; G01V 2210/6165

(57) ABSTRACT

A density inversion method comprises acquiring local gravity anomalies of a target body to be measured at many measurement points within a target measurement area; acquiring information of distance between a center position of an area the target body being located and a specified boundary of the target measurement area; determining a target inversion depth to be used in density inversion for the target body based on the information of distance and the specified depth; and substituting the local gravity anomaly of the target body at each measurement point and the target inversion depth into a preset layer density inversion formula which is a transform formula of a density inversion formula in the case of a constant density in a longitudinal cross-section, to obtain a density distribution of the target body in a transverse cross-section. The accuracy of the density distribution obtained through the density inversion can be improved.

### CROSS-REFERENCE TO RELATED APPLICATIONS

The present application claims the priority of the Chinese patent application No. 202110768231.7, filed with the China National Intellectual Property Administration on Jul. 5, 2021, entitled “Density Inversion Method, Apparatus, and Electronic Device”, the disclosure of which is incorporated herein by reference in its entirety.

### FIELD OF THE INVENTION

The present application relates to the field of geophysical exploration and, in particular, to a density inversion method, apparatus and electronic device.

### BACKGROUND ART

Density inversion is a method of inverting the density of subsurface target bodies based on gravity anomalies. The target bodies can be geological bodies such as ores, oil fields, caves.

In the related technology, in order to invert the density of a target body, gravity data at each measurement point in a measurement area set up for the target body is measured by a gravity measurement device. The gravity data is processed for latitudinal correction, topographic correction, etc., so as to obtain a Bouguer gravity anomaly at each measurement point. The regional gravity anomalies in the Bouguer gravity anomalies at each measurement point are eliminated to obtain the local gravity anomalies at each measurement point. Finally, the target body is subjected to volume inversion based on the local gravity anomalies at each measurement point to obtain the density distribution in the three-dimensional space of the target body.

Since the measurement points in the measurement area are distributed in two dimensions, i.e., the number of measurement points is Nx*Ny, and the volumetric inversion is to obtain the density distribution in a three-dimensional space, i.e., to obtain the density values of the Nz*Nx*Ny position points in the target body. This is clearly an underdetermined problem, i.e., the density distribution obtained through the related technologies is not accurate.

### SUMMARY OF THE INVENTION

It is an object of embodiments of the present application to provide a density inversion method, apparatus and electronic device to improve the accuracy of the density distribution obtained by density inversion.

In a first aspect, an embodiment of the present application provides a density inversion method comprising: acquiring local gravity anomalies of a target body to be measured at a plurality of measurement points within a target measurement area, wherein an area where the target body to be measured is located is in the target measurement area, and the target body to be measured is a geological body at a specified depth; acquiring information of distance between a center position of the area where the target body to be measured is located and a specified boundary, wherein the specified boundary is a boundary of the target measurement area: determining a target inversion depth to be used in density inversion for the target body to be measured based on the information of distance and the specified depth; and substituting the local gravity anomaly of the target body to be measured at each measurement point and the target inversion depth into a preset layer density inversion formula to obtain a density distribution of the target body to be measured in a transverse cross-section, wherein the layer density inversion formula is a transform formula of a density inversion formula in the case of a constant density in a longitudinal cross-section.

In an embodiment of the present application, the step of substituting the local gravity anomaly of the target body to be measured at each measurement point and the target inversion depth into a preset layer density inversion formula to obtain a density distribution of the target body to be measured in a transverse cross-section comprises: determining a wave number expression in a wave number domain corresponding to the preset layer density inversion formula: determining a minimum wave number of the wave number expression based on a maximum depth of the target body to be measured, and determining a maximum wave number of the wave number expression based on a minimum depth of the target body to be measured: converting the wave number expression into an expression with a wave number range between the maximum wave number and the minimum wave number as a target wave number expression: substituting the local gravity anomaly of the target body to be measured at each measurement point and the target inversion depth into the target wave number expression to obtain a Fourier transform expression for the density distribution at the target inversion depth; and performing a Fourier inverse transform on the Fourier transform expression to obtain the density distribution in the transverse cross-section at the target inversion depth as the density distribution of the target body to be measured in the transverse cross-section.

In an embodiment of the present application, the step of determining a target inversion depth to be used in density inversion for the target body to be measured based on the information of distance and the specified depth comprises: determining whether a magnitude relationship between the information of distance and the specified depth satisfies a preset difference condition: if it satisfies, using the specified depth as the target inversion depth to be used in density inversion for the target body to be measured: if not, calculating an equivalent depth of the target body to be measured based on the information of distance and the specified depth as the target inversion depth to be used in density inversion for the target body to be measured.

In an embodiment of the present application, the step of calculating an equivalent depth of the target body to be measured based on the information of distance and the specified depth comprises: determining a windowed Green's function corresponding to the information of distance based on a specified window function and a gravity Green's function, wherein a window range of the specified window function is determined based on the information of distance: substituting the specified depth into the windowed Green's function to obtain a Green's function value of the specified depth as a reference Green's function value; and determining, based on the gravity Green's function, a depth value with a smallest difference between a corresponding Green's function value and the reference Green's function value as the equivalent depth.

In an embodiment of the present application, a distance between adjacent measurement points among the plurality of measurement points and the specified depth satisfy a preset condition: the step of acquiring local gravity anomalies of the target body to be measured at a plurality of measurement points within a target measurement area comprises: acquiring Bouguer gravity anomalies at the plurality of measurement points within the target measurement area: determining, for each measurement point, a Bouguer gravity anomaly of the target body to be measured at the measurement point based on the Bouguer gravity anomalies at the plurality of measurement points, as a first anomaly at the measurement point, and determining a Bouguer gravity anomaly of a reference body corresponding to the target body to be measured at the measurement point as a second anomaly at the measurement point based on the Bouguer gravity anomalies at the plurality of measurement points, wherein the reference body is a geological body with a depth greater than the specified depth; and calculating, for each measurement point, a difference between the first anomaly and the second anomaly at the measurement point, as the local gravity anomaly of the target body to be measured at the measurement point.

In a second aspect, an embodiment of the present application provides a density inversion apparatus comprising: an anomaly acquisition module configured to acquire local gravity anomalies of a target body to be measured at a plurality of measurement points within a target measurement area, wherein an area where the target body to be measured is located is in the target measurement area, and the target body to be measured is a geological body at a specified depth; an information acquisition module for acquiring information of distance between a center position of the area where the target body to be measured is located and a specified boundary, wherein the specified boundary is a boundary of the target measurement area: a depth determination module for determining a target inversion depth to be used in density inversion for the target body to be measured based on the information of distance and the specified depth; and a density determination module for substituting the local gravity anomaly of the target body to be measured at each measurement point and the target inversion depth into a preset layer density inversion formula to obtain a density distribution of the target body to be measured in a transverse cross-section, wherein the layer density inversion formula is a transform formula of a density inversion formula in the case of a constant density in a longitudinal cross-section.

In an embodiment of the present application, the density determination module is configured to: determine a wave number expression in a wave number domain corresponding to the preset layer density inversion formula: determine a minimum wave number of the wave number expression based on a maximum depth of the target body to be measured, and determine a maximum wave number of the wave number expression based on a minimum depth of the target body to be measured: convert the wave number expression into an expression with a wave number range between the maximum wave number and the minimum wave number as a target wave number expression: substitute the local gravity anomaly of the target body to be measured at each measurement point and the target inversion depth into the target wave number expression to obtain a Fourier transform expression for the density distribution at the target inversion depth; and perform a Fourier inverse transform on the Fourier transform expression to obtain the density distribution in the transverse cross-section at the target inversion depth as the density distribution of the target body to be measured in the transverse cross-section.

In an embodiment of the present application, the depth determination module is specifically configured to: determine whether a magnitude relationship between the information of distance and the specified depth satisfies a preset difference condition: if it satisfies, use the specified depth as the target inversion depth to be used in density inversion for the target body to be measured: if not, calculate an equivalent depth of the target body to be measured based on the information of distance and the specified depth as the target inversion depth to be used in density inversion for the target body to be measured.

In an embodiment of the present application, the depth determination module is configured to: determine a windowed Green's function corresponding to the information of distance based on a specified window function and a gravity Green's function, wherein a window range of the specified window function is determined based on the information of distance: substitute the specified depth into the windowed Green's function to obtain a Green's function value of the specified depth as a reference Green's function value; and determine, based on the gravity Green's function, a depth value with a smallest difference between a corresponding Green's function value and the reference Green's function value as the equivalent depth.

In an embodiment of the present application, a distance between adjacent measurement points among the plurality of measurement points and the specified depth satisfy a preset condition: the anomaly acquisition module is configured to: acquire Bouguer gravity anomalies at the plurality of measurement points within the target measurement area: determine, for each measurement point, a Bouguer gravity anomaly of the target body to be measured at the measurement point based on the Bouguer gravity anomalies at the plurality of measurement points, as a first anomaly at the measurement point, and determine a Bouguer gravity anomaly of a reference body corresponding to the target body to be measured at the measurement point based on the Bouguer gravity anomalies at the plurality of measurement points, as a second anomaly at the measurement point, wherein the reference body is a geological body with a depth greater than the specified depth; and calculating, for each measurement point, a difference between the first anomaly and the second anomaly at the measurement point, as the local gravity anomaly of the target body to be measured at the measurement point.

In a third aspect, an embodiment of the present application further provides an electronic device comprising a processor, a communication interface, a memory, and a communication bus, wherein the processor, the communication interface, and the memory perform communication with each other via the communication bus: the memory is configured to store a computer program; and the processor is configured to implement any method described in the first aspect in the execution of the program stored on the memory.

In a fourth aspect, an embodiment of the present application further provides a computer-readable storage medium storing a computer program, and when the computer program is executed by a processor, any method described in the first aspect is implemented.

Beneficial effects of embodiments of the present application are as follows.

The density inversion method provided in the embodiment of the present application, after obtaining local gravity anomalies of the target body to be measured at a plurality of measurement points within the target measurement area, can acquire information of distance between the center position of the area in which the target body to be measured is located and the specified boundary, then determine the target inversion depth to be used in density inversion for the target body to be measured based on the information of distance and the specified depth, and substitute the local gravity anomaly of the target body to be measured at each measurement point and the target inversion depth into the preset layer density inversion formula to obtain the density distribution of the target body to be measured in the transverse cross-section. Since the layer density inversion formula is the transform formula of the density inversion formula in the case of constant density in the longitudinal cross-section, it is understandable according to the density distribution calculated using the layer density inversion formula that the density does not change with the depth near the depth where inversion is to be done, and only the density change in the transverse cross-section is taken into account, which makes it possible to obtain a definite solution for the density inversion, thereby improving the accuracy of the density distribution obtained through the density inversion.

It is understandable that implementation of any of the products or methods of the present application does not necessarily attain all of the above advantages at the same time.

### BRIEF DESCRIPTION OF THE DRAWINGS

In order to explain the embodiments of the present invention and the technical solutions in the prior art more clearly, the drawings used in the embodiments and the prior art will be briefly described hereinafter. Apparently, the drawings are only embodiments of the present application. For those ordinary skilled in the art, other drawings can be obtained according to these drawings without inventive effort.

FIG. 1 is a flowchart of a first density inversion method provided by an embodiment of the present application.

FIG. 2 is a flowchart of a second density inversion method provided by an embodiment of the present application.

FIG. 3 is a flowchart of a third density inversion method provided by an embodiment of the present application.

FIG. 4 is a flowchart of a fourth density inversion method provided by an embodiment of the present application.

FIG. 5 is a flowchart of a fifth density inversion method provided by an embodiment of the present application.

FIG. 6 is a schematic diagram of a structure of a density inversion apparatus provided by an embodiment of the present application.

FIG. 7 is a schematic diagram of a structure of an electronic device provided by an embodiment of the present application.

### DETAILED DESCRIPTION OF THE INVENTION

In order to make the objects, technical solutions, and advantages of the present application more clearly understood, the present application is described in further detail hereinafter with reference to the drawings and embodiments. Obviously, only some, but not all, of the embodiments of the present application are described. All other embodiments obtained by a person skilled in the art based on the embodiments of the present application without the need for creative labor fall within the scope of protection of the present application.

In order to improve the accuracy of the density distribution obtained through density inversion, embodiments of the present application provide a density inversion method, apparatus, and electronic device.

The terminology involved in the embodiments of the present application is first explained below.

Bouguer Gravity Anomaly: The gravity field data after removing the effects of solid tides (deformation of the earth caused by the sun and moon), latitude and longitude, elevation, and intermediate density (density between the measurement plane and the datum).

Regional Gravity Anomaly: The gravity anomaly caused by the density anomaly of the geological body in a deep and wide range of region that is buried deep and has a wide distribution. The characteristics of the regional gravity anomaly are is characterized by wide distribution and small gravity change gradient (slow change frequency). The regional gravity anomaly is important data for the study of regional geological structures and the division of geotectonic units. It should be noted that the term “region” does not have an absolute size concept. For example, in order to search for oil reservoir structures, the gravity anomaly caused by the entire sedimentary basin can be called a regional gravity anomaly: if oil and gas exploration is carried out directly on oil reservoir structures, the gravity anomaly caused by oil reservoir structures rather than that caused by oil and gas layers is a regional gravity anomaly.

Local Gravity Anomalies: The gravity anomaly caused by the density anomaly of the geological body in a shallow region, also known as the residual gravity anomaly, or local Bugge anomaly, etc., which represents the change in the vertical component of gravity caused by the uneven density distribution of the underground geological body. The local gravity anomaly is characterized by large gravity change gradient (fast change frequency).

In the related technology, in order to invert the density of a target body, gravity data at each measurement point in a measurement area set for the target body is measured by a gravity measurement device, and the gravity data is then processed for latitudinal correction, topographic correction, etc., to obtain a Bouguer gravity anomaly at each measurement point. Then, a regional gravity anomaly in the Bouguer gravity anomaly at each measurement point is eliminated, and a local gravity anomaly at each measurement point is obtained. Finally, the target body is subjected to a volume inversion through the local gravity anomaly at each measurement point to obtain the density distribution of the target body in three-dimensional space.

The density inversion formula used for the above volume inversion of the target body is:

$$data ( x , y , z ) = M \int \int \int \frac{σ ( ξ , η , ζ ) ( ζ - z ) d ξ d η d ζ}{{[ {( x - ξ )}^{2} + {( y - η )}^{2} + {( z - ζ )}^{2} ]}^{3 / 2}}$$

wherein data(x,y,z) denotes the local gravity anomaly of the target body at the measurement point (x, y, z), which is located on the ground when z=0, σ(ξ, η, ζ) denotes the density at the subsurface point (ξ, η, ζ), and M represents the gravity constant.

Since the measurement points in the measurement area are distributed in two dimensions, i.e., the number of measurement points is Nx*Ny, and the volumetric inversion is to obtain the density distribution in a three-dimensional space, i.e., to obtain the density values of the Nz*Nx*Ny position points in the target body. This is clearly an underdetermined problem, i.e., the density distribution obtained through the related technologies is not accurate.

In order to solve the technical problem of inaccuracy of the density distribution obtained by performing volume inversion in the related technology, embodiments of the present application provide a density inversion method comprising:
acquiring local gravity anomalies of a target body to be measured at a plurality of measurement points within a target measurement area, wherein an area where the target body to be measured is located is in the target measurement area, and the target body to be measured is a geological body at a specified depth;
acquiring information of distance between a center position of the area where the target body to be measured is located and a specified boundary, wherein the specified boundary is a boundary of the target measurement area;
determining a target inversion depth to be used in density inversion for the target body to be measured based on the information of distance and the specified depth;
substituting the local gravity anomaly of the target body to be measured at each measurement point and the target inversion depth into a preset layer density inversion formula to obtain a density distribution of the target body to be measured in a transverse cross-section,
wherein the layer density inversion formula is a transform formula of a density inversion formula in the case of a constant density in a longitudinal cross-section.

Since the layer density inversion formula is the transform formula of the density inversion formula in the case of constant density in the longitudinal cross-section, it is understandable according to the density distribution calculated using the layer density inversion formula that the density does not change with the depth near the depth at which inversion is to be done, and only the density change in the transverse cross-section is taken into account, which makes it possible to obtain a definite solution for the density inversion, thereby improving the accuracy of the density distribution obtained through the density inversion.

It should be noted that the embodiments of the present application can be applied to various types of electronic devices, such as personal computers, servers, smart terminals, and other devices with data processing capabilities. Moreover, the density inversion method provided by the embodiments of the present application may be realized by means of software, hardware, or a combination thereof.

The density inversion method of the embodiment of the present application will be described in detail below in conjunction with the drawings.

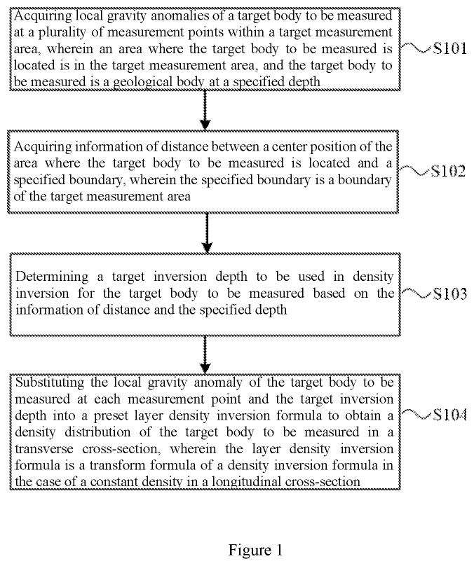

As shown in FIG. 1, the density inversion method provided by the embodiment of the present application includes the following steps:
S101, acquiring local gravity anomalies of a target body to be measured at a plurality of measurement points within a target measurement area. An area where the target body to be measured is located is in the target measurement area, and the target body to be measured is a geological body at a specified depth.

The above target body to be measured is a geological body at a specified depth, which can be understood as a three-dimensional area of the underground. For example, when it is necessary to measure the density distribution in a three-dimensional area underground that start at a specified depth of 500 m and extends downwards with a length of 100 m, a width of 50 m, and a height of 50 m, this underground three-dimensional area can be regarded as the target body to be measured. The specified depth is the burial depth of the target body to be measured.

The target measurement area is an area set for measuring the gravity field values for the target body to be measured. In order to perform the density inversion, it is necessary to determine the local gravity anomalies of the target body to be measured on the ground based on the measured gravity field values. The local gravity anomaly of the target to be measured on the ground means the anomaly of the ground gravity field value caused by the density anomaly of the target to be measured.

The target measurement area is a designated area for collecting gravity field values. Theoretically, the larger the range of the target measurement area, the better, and the larger the range, the greater the range of gravity field values that can be collected.

In order to improve the accuracy of the density obtained from the inversion, it is necessary to determine, for the target body to be measured, the measurement area for measuring the gravity magnitude and the distribution positions of the measurement points within the measurement area before acquiring the Bouguer gravity anomaly. In other words, before acquiring the Bouguer gravity anomaly, it is necessary to determine the coordinates of the measurement points, the measurement distance (i.e., the distance between adjacent measurement points), and the boundary of the measurement area.

In order to clearly describe the technical solution of the embodiment, the definition of field width proposed by the inventors of this application is given.

Definition of gravity field width: The gravity field width AX is the horizontal distance from the point where the maximum absolute value of the basic field (unit density field) drops by 80% (about 1 dB, 10 log) to the point of absolute maximum value. The wider the spatial spread of the gravity field, the greater the field width and the smaller the cutoff frequency. The ratio of the field value Gzx of the gravity field at point x to the absolute maximum value Gz0 of the gravity field is:

$$\frac{{G}_{zx}}{{G}_{z 0}} = {cos}^{3} ( α )$$

From this formula, it is clear that when the ratio is 0.8, a is approximately 21.83.

In this embodiment, the boundary of the measurement region may start at a boundary of a target body to be measured, and the boundary of the measurement region is greater than or equal to twice the specified depth. If there is a plurality of target bodies, the boundary of the measurement region is greater than or equal to twice the maximum specified depth.

In this embodiment, the distance between adjacent measurement points and the specified depth satisfies a preset condition.

Optionally, in one implementation, the preset condition may be:

$$Δ X \leq \frac{h}{a}$$

where ΔX is the distance between adjacent measurement points, h is the specified depth, and a is a preset parameter.

Optionally, in order to make the measured gravity data recoverable, a may be 2.5, i.e., the measurement distance is less than or equal to one 2.5^{th}(1/2.5) of the specified depth, that is:

$$Δ X \leq \frac{h}{2.5}$$

According to the definition of the field width of the gravity field, when measuring with the field width, it can be ensured that at least one point near the maximum gravity field value (i.e., the maximum absolute value) (within the range of amplitude variation from 1 to 94.2%) is measured, thus ensuring that the shape distortion of the measured gravity field curve will not be too large, or in other words, the anomaly with a depth equal to or greater than 2.5 times the measurement distance can be well recorded in the measured gravity data.

Secondly, the cutoff frequency change of the anomaly with a depth greater than or equal to 2.5 times of the measurement distance is moderate. If the field width is used as the measurement distance, the amplitude at the cutoff frequency is about 28.7% of the maximum amplitude, with a slight loss of high frequencies. If 2 times the field width is used as the measurement distance, the amplitude at the cutoff frequency is about 53.5% of the maximum amplitude, with a severe loss of medium and high frequencies. If ½ of the field width is used as the measurement distance, the amplitude at the cutoff frequency is about 8.2% of the maximum amplitude, with almost no loss. Therefore, if the measurement distance is less than the field width, the measurement points are too dense, and if the measurement distance is greater than the field width, the measurement points are too sparse. Thus, the measurement spacing is optimal near the field width.

In the case where the boundary of the measurement area and the distance between adjacent measurement points are determined, the coordinates of each measurement point can be calculated, so that the Bouguer gravity anomaly can be measured at each measurement point, and the local gravity anomaly of the target body to be measured at each measurement point can be further calculated. The specific calculation of local gravity anomaly will be described in detail in the following and will not be repeated here.
S102, acquiring information of distance between a center position of the area where the target body to be measured is located and a specified boundary, wherein the specified boundary is a boundary of the target measurement area.

The information of distance between the center position of the area where the target body to be measured is located and the specified boundary is a distance value between the center position and the specified boundary. If the target measurement area is a circular area, the information of distance can be understood as an area radius of the target measurement area.
S103, determining a target inversion depth to be used in density inversion for the target body to be measured based on the information of distance and the specified depth.

The target inversion depth may be different in different situations. The target inversion depth may be a specified depth or an equivalent depth determined based on the specified depth. The equivalent depth refers to a depth possessed by the Green's function that is closest to the frequency response of the characteristic function thereof after truncation of an anomaly at a certain depth, which is referred to as the equivalent depth of the truncated anomaly in this embodiment. That is, the depth used for the inversion does not necessarily adopt the true depth of the target layer where the target body to be measured is located but is affected by the data collection range. If the collection range is more than twice the burial depth of the target body to be measured, the true depth of the target body to be measured can be used for the inversion. Otherwise, the inversion needs to be performed with an equivalent depth that is less than the true depth of the target body to be measured.
S104, substituting the local gravity anomaly of the target body to be measured at each measurement point and the target inversion depth into a preset layer density inversion formula to obtain a density distribution of the target body to be measured in a transverse cross-section. The layer density inversion formula is a transform formula of a density inversion formula in the case of a constant density in a longitudinal cross-section.

When the density is constant in the longitudinal cross-section, i.e., the density σ(x,y,h) of a three-dimensional point within the target body to be measured does not change with depth near h, the above density inversion formula is transformed to obtain the transform formula:

$$data ( x , y , h ) = \int \int σ ( ξ , η , h ) G ( x - ξ , y - η , h ) Δ hd ξ d η$$

This is the layer density inversion formula mentioned in this embodiment. By substituting the local gravity anomaly of the target body to be measured at each measurement point into the layer density inversion formula, the density distribution of the target body to be measured in the transverse cross-section can be obtained.

In this embodiment, since the layer density inversion formula is a transform formula of the density inversion formula in the case of constant density in the longitudinal cross-section, in the density distribution obtained by utilizing the layer density inversion formula, it can be understood that the density does not change with the depth near the inversion depth, and only the density change in the transverse cross-section is taken into account, so that a definite solution of the density inversion can be obtained, and the accuracy of the density distribution obtained through the density inversion can be improved.

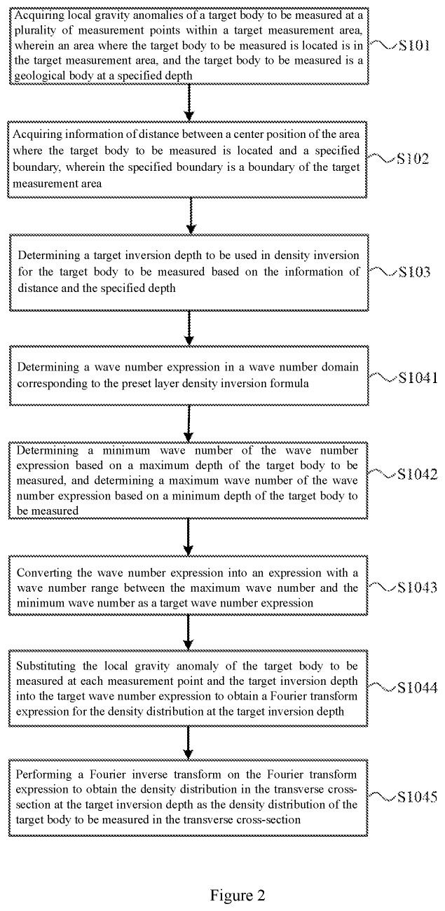

Based on the embodiment of FIG. 1, as shown in FIG. 2, in the density inversion method provided in another embodiment of the present application, S104 comprises:
S1041, determining a wave number expression in a wave number domain corresponding to the preset layer density inversion formula.

In this case, the wave number expression in the wave number domain corresponding to the preset layer density inversion formula is:

$$F ( σ ) = \frac{F ( data )}{2 π M Δ h} {e}^{k h}$$

where k is the wave number, F(σ) is the density Fourier transform, F(data) is the Fourier transform of the local gravity anomalies of the target body to be measured at a plurality of measurement points, M is the gravity constant, Δh is the thickness of the target body to be measured, and h is the target inversion depth.

Δh can be used as a parameter to transform the result into a reasonable density interval. That is, in the inversion calculation process, the effect of thickness is not taken into account, and then the wave number expression can also be expressed as:

$$\{ \begin{matrix}F ( {σ}^{′} ) = \frac{F ( data )}{2 π M} {e}^{k h} \\ σ = σ ’ * scal\end{matrix}$$

where scal is a scaling factor that acts on the inversion result σ′ to convert the inversion result σ′ into a reasonable range.
S1042, determining a minimum wave number of the wave number expression based on a maximum depth of the target body to be measured, and determining a maximum wave number of the wave number expression based on a minimum depth of the target body to be measured.

In this case, the minimum wave number=2.5 π/the maximum depth, and the maximum wave number=2.5 π/the minimum depth.

By controlling the maximum and minimum wave numbers, the frequency band range in which the inversion is performed can be controlled, and thus the signal-to-noise ratio of the inversion results can be controlled. When the signal-to-noise ratio is low in the high-frequency part of the anomaly, the maximum wave number can be reduced. When the signal-to-noise ratio is low in the low-frequency part of the anomaly, the minimum wave number can be increased.
S1043, converting the wave number expression into an expression with a wave number range between the maximum wave number and the minimum wave number as a target wave number expression.

When k is between the maximum and minimum wave number, K=(kx2+ky2)½ corresponding to the wave number expression is used as the target wave number expression.
S1044, substituting the local gravity anomaly of the target body to be measured at each measurement point and the target inversion depth into the target wave number expression to obtain a Fourier transform expression for the density distribution at the target inversion depth.

After determining the target wave number expression, the local gravity anomaly of the target body to be measured at each measurement point and the target inversion depth can be substituted into the target wave number expression, which in turn yields the Fourier transform expression for the density distribution.
S1045, performing a Fourier inverse transform on the Fourier transform expression to obtain the density distribution in the transverse cross-section at the target inversion depth as the density distribution of the target body to be measured in the transverse cross-section.

After obtaining the Fourier transform expression, the Fourier inverse transform can be performed on the Fourier transform expression to obtain the density distribution in the transverse cross-section at the target inversion depth. The Fourier inverse transform of the Fourier transform expression is the same as the existing technology and will not be repeated herein.

In this embodiment, since the layer density inversion formula is a transform formula of the density inversion formula in the case of constant density in the longitudinal cross-section, in the density distribution obtained by utilizing the layer density inversion formula, it can be understood that the density does not change with the depth near the inversion depth, and only the density change in the transverse cross-section is taken into account, so that a definite solution of the density inversion can be obtained, and the accuracy of the density distribution obtained through the density inversion can be improved.

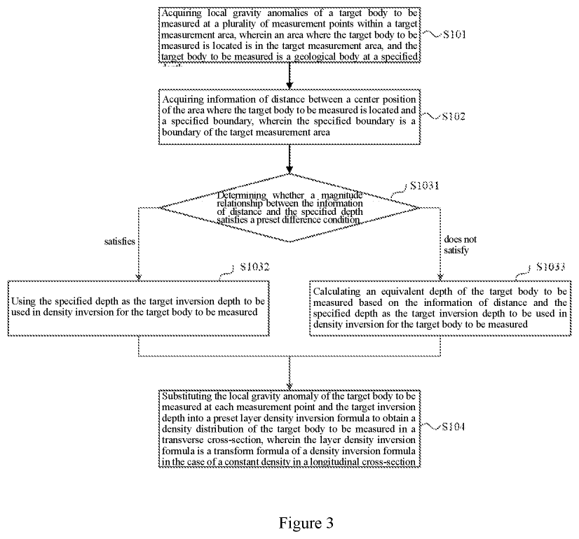

Based on the embodiment of FIG. 1, as shown in FIG. 3, in the density inversion method provided by another embodiment of the present application, S103 comprises:
S1031, determining whether a magnitude relationship between the information of distance and the specified depth satisfies a preset difference condition.

In this case, the wave number expression can be regarded as filtering the local gravity anomaly with a high pass filter, and the high frequency part will be amplified, meaning that the resolution will be increased. Meanwhile, the target inversion depth h and thickness Δh in the formula are unknown, and the target inversion depth h used in the inversion is not necessarily the specified depth of the target body to be measured, which is affected by the range of the measurement area. If the information of distance is more than twice the specified depth, it can be determined that the magnitude relationship between the information of distance and the specified depth satisfies the preset difference condition, and step S1032 is performed. Otherwise, it is determined that the magnitude relationship between the information of distance and the specified depth does not satisfy the preset difference condition, and step S1033 is performed.
S1032, using the specified depth as the target inversion depth to be used in density inversion for the target body to be measured.

In this case, the specified depth can be directly used as the target inversion depth when the information of distance is more than twice the specified depth.
S1033, calculating an equivalent depth of the target body to be measured based on the information of distance and the specified depth as the target inversion depth to be used in density inversion for the target body to be measured.

Normally, the collection of gravity data has a limited width. The range of the measurement area is usually designed to be not less than twice the specified depth of the target body to be measured. In this case, gravity data cannot be collected for a range beyond twice the specified depth. In other words, the obtained gravity curve will be truncated. The part discarded by truncation is the low-frequency part of the Green's function. That is, after weighting, the low frequency part is discarded, making the frequency higher. This means that the depth becomes shallow. Thereby, when the specified depth is used as the target inversion depth, it makes the results inaccurate. Therefore, embodiments of the present application propose to calculate the equivalent depth of the target body to be measured as the target inversion depth to be used in density inversion for the target body to be measured. The specific calculation method will be described in detail subsequently and will not be repeated herein.

In this embodiment, since the layer density inversion formula is a transform formula of the density inversion formula in the case of constant density in the longitudinal cross-section, in the density distribution obtained by utilizing the layer density inversion formula, it can be understood that the density does not change with the depth near the inversion depth, and only the density change in the transverse cross-section is taken into account, so that a definite solution of the density inversion can be obtained, and the accuracy of the density distribution obtained through the density inversion can be improved.

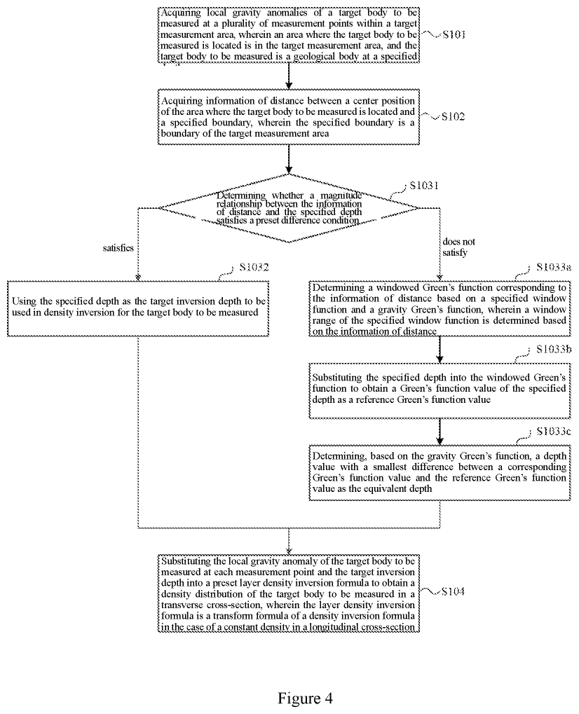

Based on the embodiment of FIG. 3, as shown in FIG. 4, in the density inversion method provided by another embodiment of the present application, S1033 comprises:
S1033a, determining a windowed Green's function corresponding to the information of distance based on a specified window function and a gravity Green's function, wherein a window range of the specified window function is determined based on the information of distance.

In this case, the windowed Green's function is:

$$GW = \{ \begin{matrix}GW , {( {x}^{2} + {y}^{2} )}^{1 / 2} <= {h}_{w} \\ 0 , others\end{matrix}$$

wherein GW is the gravity Green's function and h_{w} is the information of distance.
S1033b, substituting the specified depth into the windowed Green's function to obtain a Green's function value of the specified depth as a reference Green's function value.

In this case, after obtaining the windowed Green's function, the specified depth can be substituted into the windowed Green's function to obtain the Green's function value of the specified depth as the reference Green's function value.
S1033c, determining, based on the gravity Green's function, a depth value with a smallest difference between a corresponding Green's function value and the reference Green's function value as the equivalent depth.

In this case, the specified depth is used as a variable, and as long as the depth is found that makes the Green's function best approximate the gravity Green's function without truncation, a Green's function of equivalent depth can be derived. By using the Green's function of this depth for inversion calculation, the best estimate of the density can be obtained.

That is, let Gd denote the Green's function of the equivalent depth, and the equivalent depth is d. In order to obtain d, it is necessary to minimize the sum of the errors between Gd and the gravity Green's function GW, that is, calculate \dot{m} n ∥GW−Gd∥.

In general, the equivalent depth d can be obtained using nonlinear least squares.

In this embodiment, since the layer density inversion formula is a transform formula of the density inversion formula in the case of constant density in the longitudinal cross-section, in the density distribution obtained by utilizing the layer density inversion formula, it can be understood that the density does not change with the depth near the inversion depth, and only the density change in the transverse cross-section is taken into account, so that a definite solution of the density inversion can be obtained, and the accuracy of the density distribution obtained through the density inversion can be improved.

Optionally, in an embodiment, the distance between adjacent measurement points among the plurality of measurement points and the specified depth satisfy a preset condition.

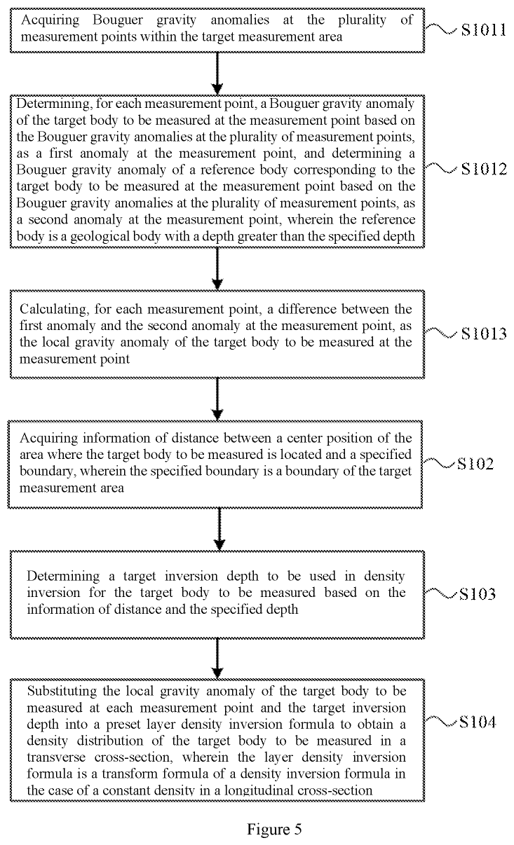

At this point, based on the embodiment of FIG. 1, as shown in FIG. 5, in the density inversion method of another embodiment of the present application, S101 comprises:
S1011, acquiring Bouguer gravity anomalies at the plurality of measurement points within the target measurement area.
S1012, determining, for each measurement point, a Bouguer gravity anomaly of the target body to be measured at the measurement point based on the Bouguer gravity anomalies at the plurality of measurement points, as a first anomaly at the measurement point, and determining a Bouguer gravity anomaly of a reference body corresponding to the target body to be measured at the measurement point based on the Bouguer gravity anomalies at the plurality of measurement points, as a second anomaly at the measurement point. The reference body is a geological body with a depth greater than the specified depth.

In this case, for the gravity field generated by any geological body, the shallower the burial depth of the geological body, the smaller the field width of the gravity field generated by the geological body, and the greater the change in the field value of the gravity field measured at the adjacent points. The deeper the burial depth of the geological body, the larger the field width of the gravity field generated by the geological body, and the smaller the change in the field value of the gravity field measured at adjacent points.

Expanding the gravity field into a Taylor series, the following expression can be obtained:

$$g = ρ ⊗ {G}_{0} + ρ ⊗ {G}_{1} + ρ ⊗ {G}_{2} + ρ ⊗ {G}_{3} + …$$

where g is the gravity field, Gᵢ denotes the part of the i-th derivative term in the Green's function series expansion, and ρ is the density.

Sampling with a single measurement interval, in the field value of twice the measurement interval, the absolute maximum value of the ratio of the third derivative term to the total field value is about 1.24%, the absolute maximum value of the ratio of the fourth derivative term to the total field value is about 0.2%, and the higher-order derivative term can be ignored. This means that when sampling with a single measurement interval, the field value of the gravity field with a field width greater than or equal to twice the measurement interval can be expressed by a low-order polynomial of adjacent points and is recursive, i.e., the recursive expression of the gravity field is:

$${g}_{r n} ( x , y ) = {g}_{l n} ( x , y ) + {g}_{r ( n + 1 )} ( x , y )$$

where gᵣₙ(x,y) is the Bouguer gravity anomaly obtained when measuring with a 2ⁿ times measurement interval, gₗₙ(x,y) is the Bouguer gravity anomaly obtained when measuring with a 2ⁿ times measurement interval, and gᵣ₍ₙ₊₁₎(x,y) is the Bouguer gravity anomaly obtained when measuring with a 2ⁿ⁺¹ times measurement interval.

The transform formula can be obtained as follows:

$${g}_{l n} ( x , y ) = {g}_{r n} ( x , y ) - {g}_{r ( n + 1 )} ( x , y )$$

That is, it can be considered that the Bouguer gravity anomaly data(h) of the shallower target body is composed of the local gravity anomaly local (h) at that depth and the Bouguer gravity anomaly data(h+Δh) of the deeper geological body, that is:

$$data ( h ) = local ( h ) + data ( h + Δ h )$$

The transform formula can be obtained as follows:

$$local ( h ) = data ( h ) - d a t a ( h + Δ h )$$

where h is the depth of the shallower target body to be measured, h+Δh is the depth of the deeper geological body, and Δh is the depth difference between the deeper geological body and the shallower target body to be measured.

Based on the above principle, the present embodiment takes the Bouguer gravity anomaly of the target body to be measured as the first anomaly at the measurement point, corresponding to gᵣₙ(x,y) or data(h) in the above formula, and takes the Bouguer gravity anomaly of a reference body with a depth equal to the sum of the specified depth and the distance between adjacent measurement points as the second anomaly at the measurement point, corresponding to gᵣ₍ₙ₊₁₎(x,y) or data(h+Δh) in the above formula.
S1013, calculating, for each measurement point, a difference between the first anomaly and the second anomaly at the measurement point, as the local gravity anomaly of the target body to be measured at the measurement point.

In this case, from the above, the difference between the first anomaly and the second anomaly is the local gravity anomaly of the target body to be measured at the measurement point. The present embodiment can obtain an accurate local gravity anomaly of the target body to be measured.

In this embodiment, since the layer density inversion formula is a transform formula of the density inversion formula in the case of constant density in the longitudinal cross-section, in the density distribution obtained by utilizing the layer density inversion formula, it can be understood that the density does not change with the depth near the inversion depth, and only the density change in the transverse cross-section is taken into account, so that a definite solution of the density inversion can be obtained, and the accuracy of the density distribution obtained through the density inversion can be improved.

Since the Bouguer gravity anomaly of the target body to be measured is formed by superimposing the local gravity anomaly of the target body to be measured and the Bouguer gravity anomaly at a deeper location, and the Bouguer gravity anomaly at the deeper location is equivalent to the Bouguer gravity anomaly of the reference body, an accurate local gravity anomaly of the target body to be measured can be obtained by calculating the difference between the first anomaly and the second anomaly. Therefore, by performing density inversion on the target body to be measured based on the local gravity anomaly of the target body to be measured, an accurate density distribution of the target body to be measured can be obtained, thereby improving the accuracy of the density distribution obtained through density inversion.

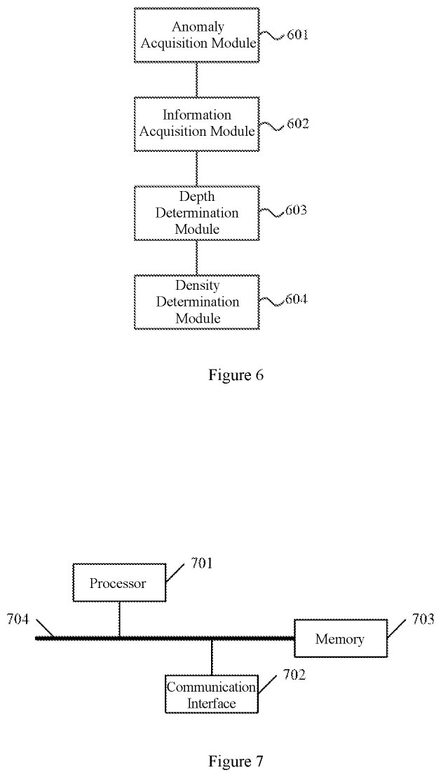

Based on the density inversion method provided by the above embodiments, as shown in FIG. 6, the present embodiment further provides a density inversion apparatus comprising:
an anomaly acquisition module 601 configured to acquire local gravity anomalies of a target body to be measured at a plurality of measurement points within a target measurement area, wherein an area where the target body to be measured is located is in the target measurement area, and the target body to be measured is a geological body at a specified depth;
an information acquisition module 602 configured to acquire information of distance between a center position of the area where the target body to be measured is located and a specified boundary, wherein the specified boundary is a boundary of the target measurement area;
a depth determination module 603 configured to determine a target inversion depth to be used in density inversion for the target body to be measured based on the information of distance and the specified depth; and
a density determination module 604 configured to substitute the local gravity anomaly of the target body to be measured at each measurement point and the target inversion depth into a preset layer density inversion formula to obtain a density distribution of the target body to be measured in a transverse cross-section, wherein the layer density inversion formula is a transform formula of a density inversion formula in the case of a constant density in a longitudinal cross-section information of distance.

Optionally, in an embodiment, the density determination module may be configured to: determine a wave number expression in a wave number domain corresponding to the preset layer density inversion formula: determine a minimum wave number of the wave number expression based on a maximum depth of the target body to be measured, and determine a maximum wave number of the wave number expression based on a minimum depth of the target body to be measured: convert the wave number expression into an expression with a wave number range between the maximum wave number and the minimum wave number as a target wave number expression: substitute the local gravity anomaly of the target body to be measured at each measurement point and the target inversion depth into the target wave number expression to obtain a Fourier transform expression for the density distribution at the target inversion depth; and perform a Fourier inverse transform on the Fourier transform expression to obtain the density distribution in the transverse cross-section at the target inversion depth as the density distribution of the target body to be measured in the transverse cross-section.

Optionally, in an embodiment, the depth determination module may be specifically configured to: determine whether a magnitude relationship between the information of distance and the specified depth satisfies a preset difference condition: if it satisfies, use the specified depth as the target inversion depth to be used in density inversion for the target body to be measured: if not, calculate an equivalent depth of the target body to be measured based on the information of distance and the specified depth as the target inversion depth to be used in density inversion for the target body to be measured.

Optionally, in an embodiment, the depth determination module may be configured to: determine a windowed Green's function corresponding to the information of distance based on a specified window function and a gravity Green's function, wherein a window range of the specified window function is determined based on the information of distance: substitute the specified depth into the windowed Green's function to obtain a Green's function value of the specified depth as a reference Green's function value; and determine, based on the gravity Green's function, a depth value with a smallest difference between a corresponding Green's function value and the reference Green's function value as the equivalent depth.

Optionally, in an embodiment, a distance between adjacent measurement points among the plurality of measurement points and the specified depth satisfy a preset condition.

The anomaly acquisition module may be configured to: acquire Bouguer gravity anomalies at the plurality of measurement points within the target measurement area: determine, for each measurement point, a Bouguer gravity anomaly of the target body to be measured at the measurement point based on the Bouguer gravity anomalies at the plurality of measurement points, as a first anomaly at the measurement point, and determine a Bouguer gravity anomaly of a reference body corresponding to the target body to be measured at the measurement point based on the Bouguer gravity anomalies at the plurality of measurement points, as a second anomaly at the measurement point, wherein the reference body is a geological body with a depth greater than the specified depth; and calculating, for each measurement point, a difference between the first anomaly and the second anomaly at the measurement point, as the local gravity anomaly of the target body to be measured at the measurement point.

In the above embodiments, since the layer density inversion formula is the transform formula of the density inversion formula in the case of constant density in the longitudinal cross-section, it is understandable according to the density distribution calculated using the layer density inversion formula that the density does not change with the depth near the depth at which inversion is to be done, and only the density change in the transverse cross-section is taken into account, which makes it possible to obtain a definite solution for the density inversion, thereby improving the accuracy of the density distribution obtained through the density inversion.

Embodiments of the present application further provides an electronic device as shown in FIG. 7, comprising a processor 701, a communication interface 702, a memory 703, and a communication bus 704, wherein the processor 701, the communication interface 702, and the memory 703 perform communication with each other via the communication bus:

The memory 703 is configured to store a computer program; and

The processor 701 is configured to implement any method described above in the execution of the program stored in the memory 703.

The above communication bus may be a peripheral component interconnection standard (PCI) bus or extended industry standard architecture (EISA) bus, etc., and can be categorized as address bus, data bus, control bus, etc. It is indicated in the figure with only one thick line, but this does not imply that there is only one bus or one type of bus.

The communication interface is configured for communication between the above electronic devices and other devices.

The memory may include random access memory (RAM) or may include non-volatile memory (NVM), such as at least one disk storage. Optionally, the memory may also be at least one storage device located away from the processor.

The processor may be a general-purpose processor, including a central processor unit (CPU), a network processor (NP), and the like: it may also be a digital signal processor (DSP), an application-specific integrated circuit (ASIC), a field-programmable gate array (FPGA) or other programmable logic device, a discrete gate or transistor logic device, and a discrete hardware component.

In yet another embodiment of the present application, there is further provided a computer-readable storage medium which internally stores a computer program, and when the computer program is executed by a processor, any of the above-described density inversion methods is implemented.

In yet another embodiment of the present application, there is also provided a computer program product comprising instructions that when run on a computer cause the computer to perform any of the density inversion methods of the above embodiments.

The above embodiments may be implemented in whole or in part by software, hardware, firmware, or any combination thereof. When implemented using software, the embodiments may be implemented in whole or in part in the form of a computer program product. The computer program product comprises one or more computer instructions. Loading and executing the computer program instructions on a computer will generate, in whole or in part, a process or function in accordance with the embodiments of the present application. The computer may be a general purpose computer, a specialized computer, a computer network, or other programmable device. The computer instructions may be stored in a computer-readable storage medium or transmitted from one computer-readable storage medium to another computer-readable storage medium. For example, computer instructions may be transmitted by wired (e.g., coaxial cable, fiber optic, digital subscriber line (DSL)) or wireless (e.g., infrared, wireless, microwave, etc.) means from one website site, computer, server, or data center to another website site, computer, server or data center. The computer-readable storage medium may be any usable medium to which a computer can access or a data storage device such as a server, data center, etc., containing one or more usable medium being integrated. The usable medium may be a magnetic medium, (e.g., floppy disk, hard disk, tape), an optical medium (e.g., DVD), or a semiconductor medium (e.g., solid state disk Solid State Disk (SSD)), and the like.

It should be noted that in this disclosure, relational terms such as “first” and “second” are used only to distinguish one entity or operation from another, and do not necessarily require or imply the existence of any such actual relationship or order between these entities or operations. Furthermore, the terms “including”, “comprising”, or any other variant thereof, are intended to cover non-exclusive inclusion, such that a process, method, article, or apparatus comprising a set of elements includes not only those elements, but also other elements not expressly listed, or further includes elements essential to such a process, method, article or equipment. In the absence of further limitation, the fact that an element is defined by the phrase “including a . . . ” does not exclude the existence of other identical element in the process, method, article, or apparatus that includes said element.

Each of the embodiments in this specification is described in a related manner, and it is sufficient to refer to each embodiment for the similarities between the embodiments, and each embodiment focuses on the differences from the other embodiments. In particular, for the device, apparatus, and system embodiments, since they basically share similar concept to the method embodiments, the descriptions thereof are relatively simple, and it is sufficient to refer to part of the description of the method embodiments for the relevant parts.

The above mentioned are only the preferred embodiments of the present application and are not intended to limit the present application. Any modifications, equivalent substitutions, improvements, etc., made within the spirit and principles of the present application should be included in the scope of protection of the present application.

1. A density inversion method comprising steps of:
acquiring local gravity anomalies of a target body to be measured at a plurality of measurement points within a target measurement area, wherein an area where the target body to be measured is located is in the target measurement area, and the target body to be measured is a geological body at a specified depth;
acquiring information of distance between a center position of the area where the target body to be measured is located and a specified boundary, wherein the specified boundary is a boundary of the target measurement area;
determining a target inversion depth to be used in density inversion for the target body to be measured based on the information of distance and the specified depth; and
substituting the local gravity anomaly of the target body to be measured at each measurement point and the target inversion depth into a preset layer density inversion formula to obtain a density distribution of the target body to be measured in a transverse cross-section,
wherein the layer density inversion formula is a transform formula of a density inversion formula in the case of a constant density in a longitudinal cross-section.

2. The method according to claim 1, wherein the step of substituting the local gravity anomaly of the target body to be measured at each measurement point and the target inversion depth into a preset layer density inversion formula to obtain a density distribution of the target body to be measured in a transverse cross-section comprises:
determining a wave number expression in a wave number domain corresponding to the preset layer density inversion formula;
determining a minimum wave number of the wave number expression based on a maximum depth of the target body to be measured, and determining a maximum wave number of the wave number expression based on a minimum depth of the target body to be measured;
converting the wave number expression into an expression with a wave number range between the maximum wave number and the minimum wave number as a target wave number expression;
substituting the local gravity anomaly of the target body to be measured at each measurement point and the target inversion depth into the target wave number expression to obtain a Fourier transform expression for the density distribution at the target inversion depth; and
performing a Fourier inverse transform on the Fourier transform expression to obtain the density distribution in the transverse cross-section at the target inversion depth as the density distribution of the target body to be measured in the transverse cross-section.

3. The method according to claim 1, wherein the step of determining a target inversion depth to be used in density inversion for the target body to be measured based on the information of distance and the specified depth comprises:
determining whether a magnitude relationship between the information of distance and the specified depth satisfies a preset difference condition;
if it satisfies, using the specified depth as the target inversion depth to be used in density inversion for the target body to be measured;
if it does not satisfy, calculating an equivalent depth of the target body to be measured based on the information of distance and the specified depth as the target inversion depth to be used in density inversion for the target body to be measured.

4. The method according to claim 3, wherein the step of calculating an equivalent depth of the target body to be measured based on the information of distance and the specified depth comprises:
determining a windowed Green's function corresponding to the information of distance based on a specified window function and a gravity Green's function, wherein a window range of the specified window function is determined based on the information of distance;
substituting the specified depth into the windowed Green's function to obtain a Green's function value of the specified depth as a reference Green's function value; and
determining, based on the gravity Green's function, a depth value with a smallest difference between a corresponding Green's function value and the reference Green's function value as the equivalent depth.

5. The method according to claim 1, wherein a distance between adjacent measurement points among the plurality of measurement points and the specified depth satisfy a preset condition; and
the step of acquiring local gravity anomalies of the target body to be measured at a plurality of measurement points within a target measurement area comprises:
acquiring Bouguer gravity anomalies at the plurality of measurement points within the target measurement area;
determining, for each measurement point, a Bouguer gravity anomaly of the target body to be measured at the measurement point based on the Bouguer gravity anomalies at the plurality of measurement points, as a first anomaly at the measurement point, and determining a Bouguer gravity anomaly of a reference body corresponding to the target body to be measured at the measurement point as a second anomaly at the measurement point based on the Bouguer gravity anomalies at the plurality of measurement points, wherein the reference body is a geological body with a depth greater than the specified depth; and
calculating, for each measurement point, a difference between the first anomaly and the second anomaly at the measurement point, as the local gravity anomaly of the target body to be measured at the measurement point.

6. A density inversion apparatus comprising:
an anomaly acquisition module configured to acquire local gravity anomalies of a target body to be measured at a plurality of measurement points within a target measurement area, wherein an area where the target body to be measured is located is in the target measurement area, and the target body to be measured is a geological body at a specified depth;
an information acquisition module configured to acquire information of distance between a center position of the area where the target body to be measured is located and a specified boundary, wherein the specified boundary is a boundary of the target measurement area;
a depth determination module configured to determine a target inversion depth to be used in density inversion for the target body to be measured based on the information of distance and the specified depth; and
a density determination module configured to substitute the local gravity anomaly of the target body to be measured at each measurement point and the target inversion depth into a preset layer density inversion formula to obtain a density distribution of the target body to be measured in a transverse cross-section, wherein the layer density inversion formula is a transform formula of a density inversion formula in the case of a constant density in a longitudinal cross-section.

7. The apparatus according to claim 6, wherein the density determination module is configured to: determine a wave number expression in a wave number domain corresponding to the preset layer density inversion formula; determine a minimum wave number of the wave number expression based on a maximum depth of the target body to be measured, and determine a maximum wave number of the wave number expression based on a minimum depth of the target body to be measured; converting the wave number expression into an expression with a wave number range between the maximum wave number and the minimum wave number as a target wave number expression; substitute the local gravity anomaly of the target body to be measured at each measurement point and the target inversion depth into the target wave number expression to obtain a Fourier transform expression for the density distribution at the target inversion depth; and perform a Fourier inverse transform on the Fourier transform expression to obtain the density distribution in the transverse cross-section at the target inversion depth as the density distribution of the target body to be measured in the transverse cross-section.

8. The apparatus according to claim 6, wherein the depth determination module is configured to determine whether a magnitude relationship between the information of distance and the specified depth satisfies a preset difference condition; if it satisfies, use the specified depth as the target inversion depth to be used in density inversion for the target body to be measured; and if it does not satisfies, calculate an equivalent depth of the target body to be measured based on the information of distance and the specified depth as the target inversion depth to be used in density inversion for the target body to be measured.

9. The apparatus according to claim 8, wherein the depth determination module is configured to determine a windowed Green's function corresponding to the information of distance based on a specified window function and a gravity Green's function, wherein a window range of the specified window function is determined based on the information of distance; substituting the specified depth into the windowed Green's function to obtain a Green's function value of the specified depth as a reference Green's function value; and determine, based on the gravity Green's function, a depth value with a smallest difference between a corresponding Green's function value and the reference Green's function value as the equivalent depth.

10. The apparatus according to claim 6, wherein a distance between adjacent measurement points among the plurality of measurement points and the specified depth satisfy a preset condition; the anomaly acquisition module is configured to acquire Bouguer gravity anomalies at the plurality of measurement points within the target measurement area; determine, for each measurement point, a Bouguer gravity anomaly of the target body to be measured at the measurement point based on the Bouguer gravity anomalies at the plurality of measurement points, as a first anomaly at the measurement point, and determine a Bouguer gravity anomaly of a reference body corresponding to the target body to be measured at the measurement point based on the Bouguer gravity anomalies at the plurality of measurement points, as a second anomaly at the measurement point, wherein the reference body is a geological body with a depth greater than the specified depth; and calculating, for each measurement point, a difference between the first anomaly and the second anomaly at the measurement point, as the local gravity anomaly of the target body to be measured at the measurement point.

11. An electronic device comprising a processor, a communication interface, a memory, and a communication bus, wherein the processor, the communication interface, and the memory communicate with each other via the communication bus;
the memory is configured to store a computer program; and
the processor is configured to execute the program in the memory to implement the method of claim 1.

12. (canceled)

13. An electronic device according to claim 11, wherein the processor is configured to execute the program in the memory wherein the step of substituting the local gravity anomaly of the target body to be measured at each measurement point and the target inversion depth into a preset layer density inversion formula to obtain a density distribution of the target body to be measured in a transverse cross-section comprises:
determining a wave number expression in a wave number domain corresponding to the preset layer density inversion formula;
determining a minimum wave number of the wave number expression based on a maximum depth of the target body to be measured, and determining a maximum wave number of the wave number expression based on a minimum depth of the target body to be measured;
converting the wave number expression into an expression with a wave number range between the maximum wave number and the minimum wave number as a target wave number expression;
substituting the local gravity anomaly of the target body to be measured at each measurement point and the target inversion depth into the target wave number expression to obtain a Fourier transform expression for the density distribution at the target inversion depth; and
performing a Fourier inverse transform on the Fourier transform expression to obtain the density distribution in the transverse cross-section at the target inversion depth as the density distribution of the target body to be measured in the transverse cross-section.

14. An electronic device according to claim 11, wherein the processor is configured to execute the program in the memory wherein the step of determining a target inversion depth to be used in density inversion for the target body to be measured based on the information of distance and the specified depth comprises:
determining whether a magnitude relationship between the information of distance and the specified depth satisfies a preset difference condition;
if it satisfies, using the specified depth as the target inversion depth to be used in density inversion for the target body to be measured;
if it does not satisfy, calculating an equivalent depth of the target body to be measured based on the information of distance and the specified depth as the target inversion depth to be used in density inversion for the target body to be measured.

15. An electronic device according to claim 11, wherein the processor is configured to execute the program in the memory wherein the step of calculating an equivalent depth of the target body to be measured based on the information of distance and the specified depth comprises:
determining a windowed Green's function corresponding to the information of distance based on a specified window function and a gravity Green's function, wherein a window range of the specified window function is determined based on the information of distance;
substituting the specified depth into the windowed Green's function to obtain a Green's function value of the specified depth as a reference Green's function value; and
determining, based on the gravity Green's function, a depth value with a smallest difference between a corresponding Green's function value and the reference Green's function value as the equivalent depth.

16. An electronic device according to claim 11, wherein the processor is configured to execute the program in the memory wherein a distance between adjacent measurement points among the plurality of measurement points and the specified depth satisfy a preset condition; and
the step of acquiring local gravity anomalies of the target body to be measured at a plurality of measurement points within a target measurement area comprises:
acquiring Bouguer gravity anomalies at the plurality of measurement points within the target measurement area;
determining, for each measurement point, a Bouguer gravity anomaly of the target body to be measured at the measurement point based on the Bouguer gravity anomalies at the plurality of measurement points, as a first anomaly at the measurement point, and determining a Bouguer gravity anomaly of a reference body corresponding to the target body to be measured at the measurement point as a second anomaly at the measurement point based on the Bouguer gravity anomalies at the plurality of measurement points, wherein the reference body is a geological body with a depth greater than the specified depth; and
calculating, for each measurement point, a difference between the first anomaly and the second anomaly at the measurement point, as the local gravity anomaly of the target body to be measured at the measurement point.
